(19) United States
(12) Patent Application Publication
(10) Pub. No.: US 2024/0160984 A1
(43) Pub. Date: May 16, 2024

(54) QUANTUM ENTANGLEMENT GENERATOR, QUANTUM ENTANGLEMENT GENERATION METHOD, AND QUANTUM COMPUTER

(71) Applicant: JAPAN SCIENCE AND TECHNOLOGY AGENCY, Saitama (JP)

(72) Inventors: Yasunobu NAKAMURA, Tokyo (JP); Yoshiki SUNADA, Tokyo (JP)

(21) Appl. No.: 18/463,815

(22) Filed: Sep. 8, 2023

Related U.S. Application Data
(63) Continuation of application No. PCT/JP2022/002831, filed on Jan. 26, 2022.

(30) Foreign Application Priority Data
Mar. 11, 2021 (JP) 2021-039384

(51) Int. Cl. G06N 10/40

(52) U.S. Cl. CPC G06N 10/40

(57) ABSTRACT

A quantum entanglement generator comprises two superconducting qubit elements, each having three electrodes, where n is an integer greater than or equal to, a coupling resonator disposed between adjacent superconducting qubit elements and a waveguide capacitively coupled to each of the superconducting qubit elements and to each other. The coupling resonator generates quantum entanglement between the adjacent superconducting qubit elements by acting a two-qubit gate between the adjacent superconducting qubit elements. The superconducting qubit elements emit the quantum entanglement as a propagating microwave photon into the waveguide, thereby generating a two-dimensional cluster state.

### BACKGROUND OF THE INVENTION

### 1. Field of the Invention

This disclosure relates to a quantum entanglement generator, quantum entanglement generation method, and a quantum computer.

### BACKGROUND ART

One of the most promising methods to realize a quantum computer is a measurement-based quantum computation (e.g., Non-Patent Literature 1 and 2).

### 2. Description of the Related Art

Non-Patent Literature 1: R. Raussendorf and H. J. Briegel, “A One-Way Quantum Computer”, Phys. Rev. Lett. 86, 5188, (2001).
Non-Patent Literature 2: R. Raussendorf, D. E. Browne, and H. J. Briegel, “Measurement-based quantum computation with cluster states”, Phys. Rev. A 68, 022312 (2003).
Non-Patent Literature 3: S. E. Economou, N. Lindner, and T. Rudolph, “Optically Generated 2-Dimensional Photonic Cluster States from Coupled Quantum Dots”, Phys. Rev. Lett. 105, 093601 (2010).
Non-Patent Literature 4: J. Ilves, S. Kono, Y. Sunada, S. Yamazaki, M. Kim, K. Koshino, Y. Nakamura “On-demand generation and characterization of a microwave time-bin qubit”, npj Quantum Information volume 6, Article number: 34 (2020).
Non-Patent Literature 5: J. M. Gambetta, A. A. Houck, Alexandre Blais, “Superconducting Qubit with Purcell Protection and Tunable Coupling”, Phys. Rev. Lett. Lett. 106, 030502 (2011).
Non-Patent Literature 6: M. Pechal, L. Huthmacher, C. Eichler, S. Zeytinoglu, A. A. Abdumalikov, Jr., S. Berger, A. Wallraff, and S. Filipp “Microwave-controlled generation of shaped single photons in circuit quantum electrodynamics”, Physical Review X 4, 041010(2014).
Non-Patent Literature 7: P. Kurpiers, P. Magnard, T. Walter, B. Royer, M. Pechal, J. Heinsoo, Y. Salathe, A. Akin, S. Storz, J.-C. Besse, S. Gasparinetti, A. Blais, A. Wallraff, “Deterministic Quantum State Transfer and Generation of Remote Entanglement using Microwave Photons”, Nature 558, 264-267 (2018).

### SUMMARY OF THE INVENTION

Measurement-based quantum computation requires preparation of large-scale quantum entanglements, called cluster states. Non-Patent Literature 3 discloses an idea to generate a cluster state of a two-dimensional photon sequence from two coupled quantum dot pairs. Non-Patent Literature 4 discloses an on-demand generation of microwave time-bin qubits by a superconducting circuit quantum electrodynamics (circuit-QED) architecture. Non-Patent Literature 5 discloses a superconducting qubit element with three electrodes. These techniques are elemental technologies for generating two-dimensional cluster states of microwave photon sequences using superconducting qubit elements. However, a specific device for generating two-dimensional cluster states of microwave photon sequences has not yet been proposed.

The present disclosure was made in view of these problems, and its purpose is to provide an apparatus for generating a two-dimensional cluster state of a microwave photon sequence.

In order to solve the above-mentioned problems, one aspect of the present disclosure is a quantum entanglement generator. The quantum entanglement generator comprises n qubit elements, where n is an integer of 2 or more, a coupling resonator disposed between adjacent qubit elements, and waveguides (for example, coaxial lines and coplanar waveguides). The quantum entanglement generator generates quantum entanglement between the adjacent qubit elements by causing a two-qubit gate between the adjacent qubit elements using the coupling resonator. The qubit elements emit the quantum entanglement as propagating microwave photons into the waveguide, thereby generating a two-dimensional cluster state.

Adjacent qubit elements may be directly coupled without using a coupling resonator. In other words, even if the qubits are directly coupled to each other, the two-qubit gate required for this method can be made to work.

Each of the n qubit elements may have three electrodes.

The quantum entanglement generator of one embodiment may comprise a photon emission resonator or photon emission qubit that transfers the quantum entanglement to propagating microwave photons and emits the propagating microwave photons into the waveguide, independently of the qubit element.

The quantum entanglement generator of one embodiment may comprise a readout resonator for reading out the state of the qubit element.

Two of the three electrodes have the shape of a circular ring cut in half with concentric contours when viewed from the direction of the waveguide.

The quantum entanglement generator of one embodiment may comprise a conductor cavity with a cavity penetrating therein, wherein the qubit element and the coupling resonator are fixed within the cavity of the conductor cavity.

The qubit element may initialize a qubit to the ground state, semi-excite the ground state to the first excited state, excite the first excited state to the second excited state, excite the ground state to the second excited state, drive a transition from the second excited state, and then emit propagating microwave photons from the resonator into the waveguide and semi-excites the first excited state to the second excited state.

The qubit element may be a superconducting qubit element.

Another aspect of the disclosure is a quantum entanglement generation method using the quantum entanglement generator described above. The method comprises initializing the qubit to a ground state, semi-exciting the ground state to a first excited state, exciting the first excited state to a second excited state, exciting the ground state to a first excited state, emitting propagating microwave photons from the resonator into the waveguide after driving a transition from the second excited state and semi-exciting the first excited state to the second excited state.

Yet another aspect of the disclosure is a quantum computer equipped with the aforementioned quantum entanglement generator.

The quantum computer of one embodiment may perform a measurement-based quantum computation in which a measurement is repeated for the quantum entanglement generated by the quantum entanglement generator.

The quantum computer of one embodiment may store temporarily a quantum entanglement generated by the quantum entanglement generator from the waveguide to the superconducting delay line as a propagating photon, make the quantum entanglement interact with the photon generating device again and perform a measurement-based quantum computation in which measurement is repeated while selecting the next measurement basis based on the result of the previous measurement using a measurement device with a basis.

Any combination of the above components and expressions of the disclosure converted among devices, methods, systems, recording media, computer programs, etc. are also valid as an aspect of the disclosure.

### BRIEF DESCRIPTION OF DRAWINGS

FIG. 1 is a schematic diagram showing one-dimensional cluster state;

FIG. 2 is a schematic diagram showing a two-dimensional cluster state;

FIG. 3 is a schematic diagram showing the generation and emission of propagating microwave photons by a device formed by coupling a qubit and a resonator;

FIG. 4 is a schematic diagram showing a state transition for the generation and emission of propagating microwave photons using the device of FIG. 3;

FIG. 5 is a schematic diagram showing the generation of a cluster state using the quantum entanglement generator of the first embodiment;

FIG. 6 is a perspective view of the quantum entanglement generator of the first embodiment;

FIG. 7 is a plan view of the superconducting qubit element in the quantum entanglement generator of FIG. 6;

FIG. 8 is a schematic diagram showing step 1 of the procedure for generating a cluster state using the quantum entanglement generator of FIG. 6;

FIG. 9 is a schematic diagram showing step 2-1 of the procedure for generating a cluster state using the quantum entanglement generator of FIG. 6;

FIG. 10 is a schematic diagram showing step 2-3 of the procedure for generating a cluster state using the quantum entanglement generator of FIG. 6;

FIG. 11 is a schematic diagram showing step 2-4 of the procedure for generating a cluster state using the quantum entanglement generator of FIG. 6;

FIG. 12 is a schematic diagram showing step 2-5 of the procedure for generating a cluster state using the quantum entanglement generator of FIG. 6;

FIG. 13 is a schematic diagram showing the procedure for generating a cluster state by repeating steps (2-1) to (2-5) “the desired photon chain length-1” times;

FIG. 14 is a flowchart showing the procedure for generating cluster states using the quantum entanglement generator of FIG. 6;

FIG. 15 is a perspective view of the quantum entanglement generator of the second embodiment; and

FIG. 16 is a perspective view of the quantum computer of the fourth embodiment.

### DETAILED DESCRIPTION OF THE INVENTION

The disclosure will now be described by reference to the preferred embodiments. This does not intend to limit the scope of the present disclosure, but to exemplify the disclosure.

The disclosure will now be described with reference to the drawings based on suitable embodiments. The embodiments are not intended to limit the disclosure, but to exemplify it. All features or combinations of features described in the embodiments are not necessarily essential to the disclosure. Identical or equivalent components, parts, and processes shown in each drawing shall be given the same symbol, and redundant explanations will be omitted where appropriate. The scale and shape of each part shown in each drawing are set for convenience in order to facilitate explanation, and are not to be construed as limiting unless otherwise noted. When terms such as “first”, “second”, etc. are used in this specification or in the claims, unless otherwise mentioned, these terms do not indicate any order or degree of importance, but are intended only to distinguish one configuration from another. In addition, in each drawing, some parts of the components that are not important in explaining embodiments are omitted.

Before describing the specific embodiments, the basic findings on which the present disclosure was established will be described herein. A quantum computer is a computer that achieves high-speed computation by utilizing quantum mechanical phenomena, and can efficiently solve some problems that are difficult to solve in a realistic computation time with a classical computer. The gate-based quantum computation, which has been the mainstream method for realizing quantum computers, a large number of qubits are fabricated one at a time and then combined to form inter-qubit wiring for calculation, and calculations are performed while performing quantum operations sequentially. While the gate-based quantum computation has been actively studied as a standard quantum computation method, it is difficult to scale up because the wiring and control become more complex as the number of qubits increases.

On the other hand, another realization method, “measurement-based quantum computation” (also called “one-way quantum computation”), first prepares a large number of qubits in a specific quantum entanglement (cluster state), and then performs calculations by measuring each of these qubits individually. In this respect, measurement-based quantum computation differs from the quantum gate method, which requires controlling the interaction between qubits (quantum gates) depending on the contents of the computation. The principle of measurement-based quantum computation is that the cluster state is a superposition of patterns of arbitrary quantum computation, and by repeating adaptive measurements on the cluster state, arbitrary computation can be performed. The advantage of measurement-based quantum computation is that once a cluster state having an appropriate quantum entanglement structure with a sufficient number of qubits is prepared at the beginning, any quantum computation can be realized by a relatively simple measurement of each qubit. Here, “a cluster state having an appropriate quantum entanglement structure” refers to a generic quantum entanglement that can realize arbitrary quantum computation using multiple inputs, and the simplest example of this is known as a “two-dimensional cluster state”. According to measurement-based quantum computation, large-scale quantum computation can be performed with relatively small hardware.

A “quantum bit” (also called a “Qubit” or “qubit”) is the smallest unit of quantum information in a quantum computer. A bit in a classical computer takes only one value, either 0 or 1. That is, the state (classical states) in this case is two states. In contrast, a quantum bit can take a state that is a quantum mechanical superposition of these two states.

“Quantum entanglement” refers to the correlation between two or more qubits in a quantum many-body system that can only be explained by quantum mechanics. Quantum entanglement is used in various information processing technologies (quantum measurement, quantum communication, quantum computation, etc.) that apply quantum mechanics. The cluster state described below is also a type of quantum entanglement.

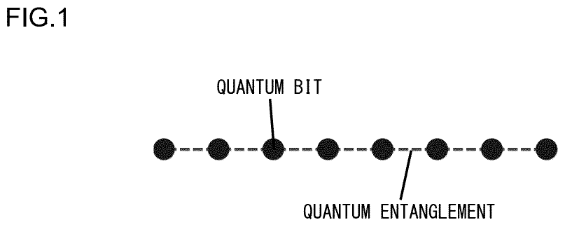

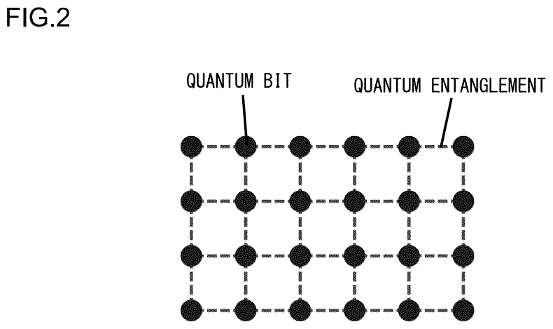

“Cluster state” is a type of quantum entanglement used in measurement-based quantum computation. When illustrating a cluster state, qubits are often represented by circles, and quantum entanglements between qubits are often represented by lines. The structure of the cluster state determines the type of quantum computation that can be performed using the cluster state. For example, a single chain of cluster states (one-dimensional cluster state) allows only one-input, one-output calculations. In contrast, in order to be able to perform arbitrary quantum calculations with multiple inputs and outputs, a two-dimensional cluster state with a mesh-like connected structure is required. FIG. 1 schematically shows a one-dimensional cluster state. FIG. 2 shows schematically a two-dimensional cluster state.

Quantum mechanics is usually applied to microscopic physical systems such as atoms and electrons. However, electronic devices such as superconducting circuits containing Josephson elements exhibit quantum mechanical behavior even though they are macroscopic physical systems. The “superconducting qubit element” uses such a superconducting circuit as a device that functions as a qubit. In other words, a superconducting qubit element is an artificially created quantum mechanical physical system on a superconducting electric circuit. Since superconducting qubit elements are relatively easy to integrate and to control device characteristics, they are expected to be a key device for realizing quantum computers. Artificial elements that function as qubits, including but not limited to superconducting qubit elements, are sometimes referred to as “qubit elements”.

Photons with energy in the microwave region are called “microwave photons”. The frequency of microwaves is on the order of 10 GHz and can be electrically controlled. Since the wavelength of microwaves is on the order of 1 cm, various devices can be designed using conductor cavities and thin-film patterns. On the other hand, the energy of microwave photons is extremely small, corresponding to a temperature of 500 millikelvin (mK). For these reasons, the generation and detection of microwave photons must be performed at extremely low temperatures.

By integrating and implementing superconducting qubit elements on a chip, macroscopic quantum circuits can be formed. However, there is a limit to the number of superconducting qubit elements that can be implemented on a single chip. Therefore, a method has been proposed to increase the total number of superconducting qubit elements by forming a quantum network by connecting chips quantum mechanically using microwave photon propagation (e.g., Non-Patent Literature 6 and 7). Microwave photons that carry quantum information between qubits are sometimes called “propagating microwave photons”.

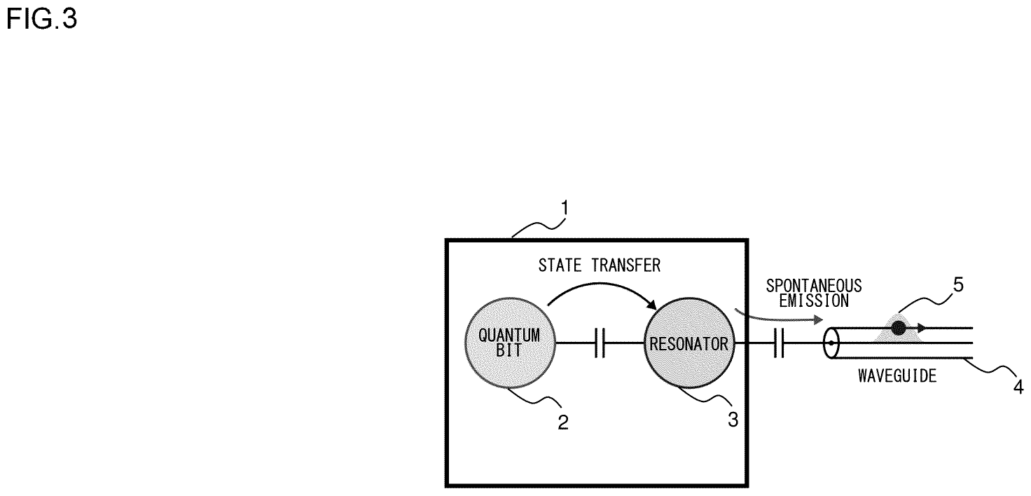

FIG. 3 illustrates the generation and emission process of propagating microwave photons. FIG. 3 shows a system in which device 1 is coupled to waveguide 4. Device 1 is configured by capacitively coupling a qubit 2 and a resonator 3. The process of generating propagating microwave photons 5 using device 1 and emitting the generated propagating microwave photons 5 into a waveguide 4 (such as a coaxial line) capacitively coupled to resonator 3 is described below.

First, the qubit 2 is set to the desired quantum state. Next, microwaves are irradiated to the qubit 2, thereby transferring the quantum state of the qubit to the resonator 3. As a result, the resonator 3 has a photon state corresponding to the quantum state of the qubit 2. Finally, the photon state of resonator 3 spontaneously emits into the waveguide 4, generating a pulse of propagating microwave photons 5.

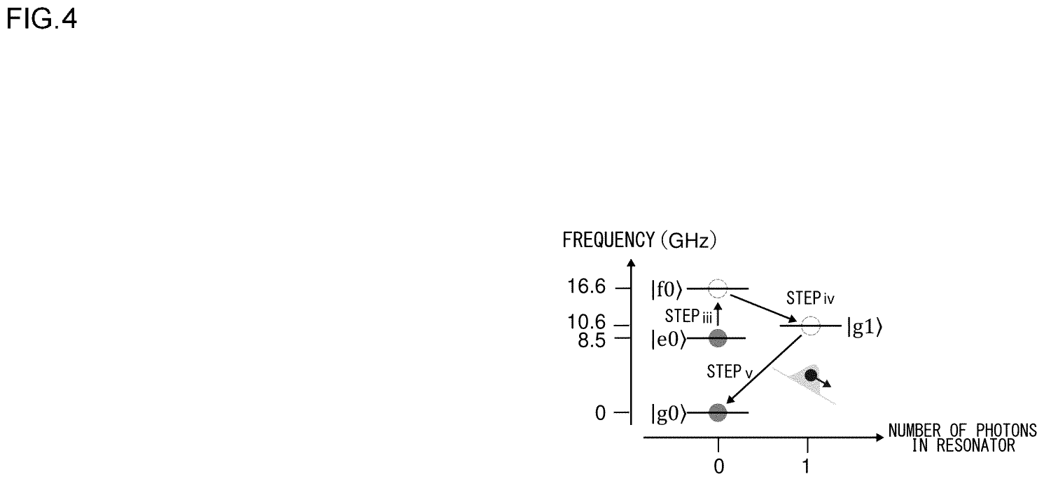

FIG. 4 shows the state transition diagram for the generation and emission of propagating microwave photons using the device in FIG. 3. Referring to FIG. 4, the procedure for generating one pulse of propagating microwave photons is described below. In this example, the qubit is a three-level system with ground state |g>, first excited state |e>, and second excited state |f>. It is also assumed that there are two quantum states in the resonator: a vacuum state with zero photons |0> and a one-photon state with one photon |1>. Hereafter, the letter on the left side in ket 1> is the state of the qubit, and the letter on the right side in ket 1> is the number of photons in the resonator. For example, |e0> indicates that the qubit is in the first excited state and the number of photons in the resonator is 0.

In this example, the frequency corresponding to the energy of each state of the system with respect to |g0> is as follows.
   |g0>: 0 GHz
   |e0>: 8.5 GHz
   |g1>: 10.6 GHz
   |f0>: 16.6 GHz

Propagating microwave photons are generated by the following five steps.
(Step i) Initialize the qubit to the ground state |g>.
(Step ii) Set the qubit to the desired state α|g>+β|e>.
(Step iii) Excite the first excited state |e> to the second excited state |f> by irradiating the qubit with microwaves of a frequency equivalent to the energy difference between the second excited state |f> and the first excited state |e> (16.6 GHz-8.5 GHz=8.1 GHz).
(Step iv) The transition from the state |f0> to the state 1g1> is driven by irradiating microwaves of a frequency (16.6 GHz-10.6 GHz=6.0 GHz) equivalent to the energy difference between the state 1f0> and the state |g1>. This conditionally excites the resonator when the qubit is in the second excited state |f>, and the state α |g>+β|e> of the qubit is transferred to the quantum state a |0>+β|1> of the resonator.
(Step v) Spontaneous emission from the resonator into the waveguide generates a pulse of propagating microwave photons a |0>+β|1>. The state of the system returns to |g0>. In this specification, as described above, the notations |f0>,|g1>, etc. are used to express the quantum state of the entire device, while the notations |f>,|g>, etc. are used when focusing only on the qubits (the same applies hereinafter).

The above procedure can also be performed for devices with photon emission qubits instead of resonators. In this case, the vacuum state and the one-photon state of the resonator correspond to the ground state and the first excited state of the photon emission qubit, respectively.

As described below, a similar procedure can also be used to generate a state of propagating microwave photon sequences entangled in a chain. In the embodiments described below, propagating microwave photons play an important role in the generation of cluster states.

### The First Embodiment

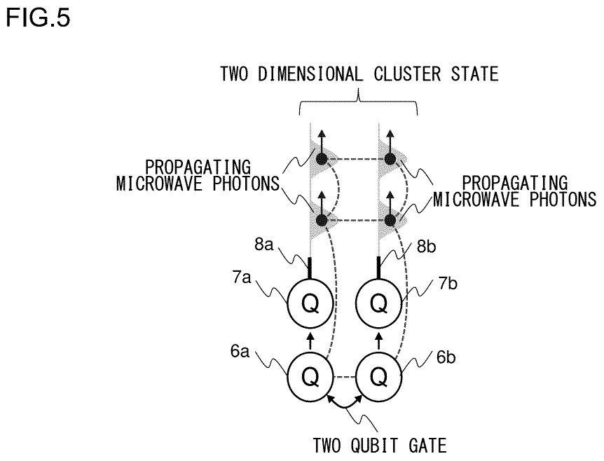

FIG. 5 schematically illustrates the generation of a cluster state using the quantum entanglement generator of the first embodiment. In this device, a photon emission qubit is used instead of a photon emission resonator. This quantum entanglement generator has two entanglement generation qubits 6a and 6b, two photon emission qubits 7a and 7b coupled to the entanglement generation qubits 6a and 6b, respectively, and microwave waveguides 8a and 8b coupled to the photon emission qubits 7a and 7b. The system consisting of the entanglement generation qubits 6a, photon emission qubits 7a, and microwave waveguide 8a is called the first column, and the system consisting of the entanglement generation qubits 6b, photon emission qubits 7b, and microwave waveguide 8b is called the second column. A two-qubit gate can act between two adjacent entanglement generation qubits 6a and 6b.

The two-qubit gate between the two entanglement generation qubits 6a and 6b generates quantum entanglement between the first and second columns. As described above, depending on the state of the entanglement generation qubits, the photon emission qubits 7a and 7b can be conditionally excited. The excitation of the photon emission qubits is then spontaneously emitted into the microwave waveguides 8a and 8b, which can generate a series of propagating microwave photons with quantum entanglement between the entanglement generation qubits. By applying a two-qubit gate between the entanglement generation qubits each time a propagating microwave photon is generated, a two-dimensional cluster state is generated.

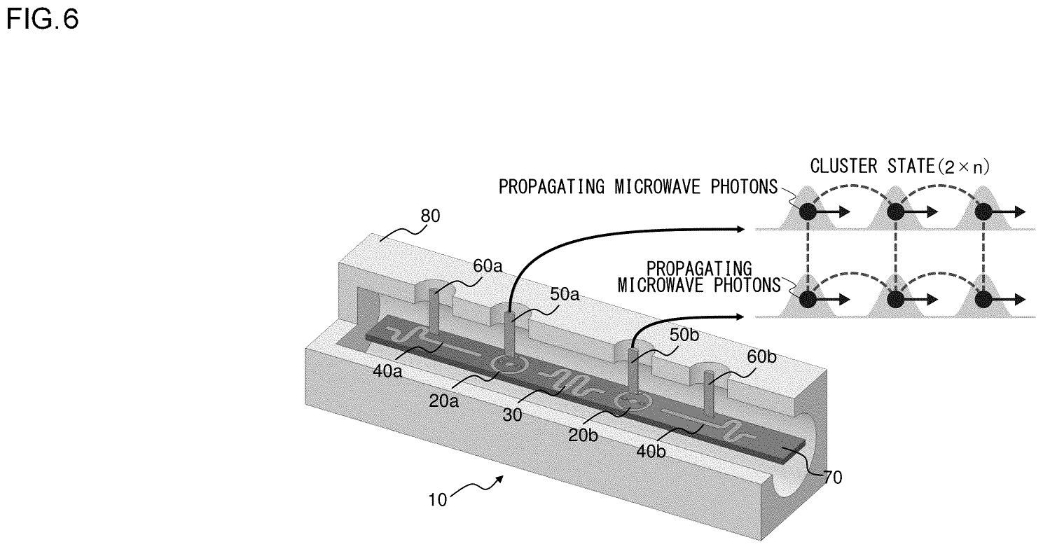

FIG. 6 schematically shows the quantum entanglement generator 10 of the first embodiment. The quantum entanglement generator 10 has superconducting qubit elements 20a and 20b, coupling resonator 30, readout resonators 40a and 40b, waveguides 50a and 50b, readout lines 60a and 60b, and conductor cavity 80. The superconducting qubit elements 20a and 20b comprise entanglement generation qubits and photon emission qubits, respectively. In other words, this quantum entanglement generator 10 implements the entanglement generation qubit 6a and the photon emission qubit 7a of FIG. 5 integrated into the superconducting qubit element 20a. Similarly, the entanglement generation qubit 6b and the photon emission qubit 7b are implemented in the form of being integrated into the superconducting qubit element 20b.

The readout resonator 40a, the superconducting qubit element 20a, the coupling resonator 30, the superconducting qubit element 20b, and the readout resonator 40b are arranged in a chain on the silicon substrate 70, from left to right in FIG. 6. The readout resonator 40a, the superconducting qubit element 20a, the coupling resonator 30, the superconducting qubit element 20b, and the readout resonator 40b are fabricated, for example, by dry etching of a niobium thin film.

The superconducting qubit element 20a and the coupling resonator 30 are capacitively coupled to each other. Similarly, the superconducting qubit element 20b and the coupling resonator 30 are capacitively coupled to each other.

The superconducting qubit element 20a and the readout resonator 40a are capacitively coupled to each other. Similarly, the superconducting qubit element 20b and the readout resonator 40b are capacitively coupled to each other.

The superconducting qubit element 20a and the waveguide 50a are capacitively coupled to each other. Similarly, the superconducting qubit element 20b and the waveguide 50b are capacitively coupled to each other.

The readout resonator 40a and the readout line 60a are capacitively coupled to each other. Similarly, readout resonator 40b and readout line 60b are capacitively coupled to each other.

The conductor cavity 80 is an aluminum block with a cylindrical cavity inside. A silicon substrate 70 is fixed inside the cavity of conductor cavity 80. The conductor cavity 80 is provided with through holes at positions corresponding to directly above the readout resonator 40a, directly above the superconducting qubit element 20a, directly above the superconducting qubit element 20b, and directly above the readout resonator 40b, respectively. Through these through holes, waveguides that are readout line 60a, waveguide 50a, waveguide 50b, and readout line 60b are inserted, respectively. As a result, the conductor cavity 80 forms the outer conductor, and the coupling resonator 30 and readout resonators 40a and 40b form the inner conductor. As a result, the quantum entanglement generator 10 has the structure of a coaxial line resonator. Coaxial line resonators have the advantage of low internal loss due to their larger mode volume compared to two-dimensional resonators created using coplanar lines and the like. Furthermore, coaxial line resonators have a simple structure and can be easily fabricated at low cost.

The readout resonators 40a and 40b are formed, for example, by a thin superconducting thin film wire made by dry etching of a niobium thin film. The readout resonators 40a and 40b are used to calibrate the quantum entanglement generator 10 and to read out the state of the quantum bits for entanglement generation, and are not involved in the actual generation of microwave photon sequences. Therefore, it is noted that they are not essential components of this system.

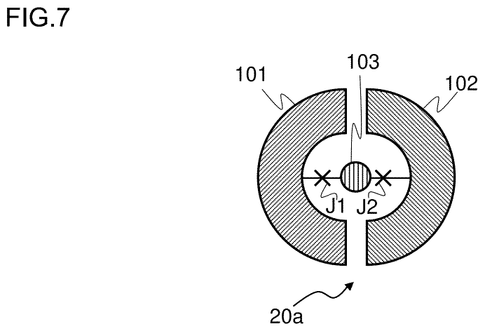

FIG. 7 illustrates a plan view of a superconducting qubit element 20a configured with three electrodes as an example of a superconducting qubit element in the quantum entanglement generator 10 of FIG. 6. The superconducting qubit element 20a has a first electrode 101, a second electrode 102, and a third electrode 103. The first electrode 101 and the second electrode 102 both have the shape of a circular ring cut in half with concentric contours. The third electrode 103 has a circular shape. The first electrode 101 and the second electrode 102 are arranged facing each other with the third electrode 103 between them. The first electrode 101 and the third electrode 103 are joined by a Josephson junction J1. Similarly, the second electrode 102 and the third electrode 103 are joined by a Josephson junction J2.

The superconducting qubit element 20a can function as an entanglement generation qubit or as a photon emission qubit, depending on the oscillation mode of the electromagnetic field generated by the first electrode 101, the second electrode 102 and the third electrode 103. For example, when the first electrode 101 is given a positive potential, the second electrode 102 a zero potential, and the third electrode 103 a negative potential, the mode of the electromagnetic field generated is strongly coupled to the adjacent superconducting qubit. Thus, in this case, the superconducting qubit element 20a functions as an entanglement generation qubit. On the other hand, for example, when the first electrode 101 is given a positive potential, the second electrode 102 a negative potential, and the third electrode 103 a positive potential, the mode of the electromagnetic field generated is strongly coupled to the coaxial line used as a waveguide in this embodiment. Therefore, in this case, the superconducting qubit element 20a functions as a photon emission qubit.

Conventional superconducting qubits, e.g., transmon qubits, are composed of a circuit consisting of one Josephson junction and one capacitor connected in parallel. In this case, there are two electrodes (i.e., one capacitor). Unlike the present embodiment, this superconducting qubit cannot realize the functions of both entanglement generation qubits and photon emission qubits. In this respect, the present embodiment has a remarkable difference from conventional superconducting qubits.

The structure and operation of the superconducting qubit element 20b are the same as those of the superconducting qubit element 20a described above, therefore a detailed description is omitted.

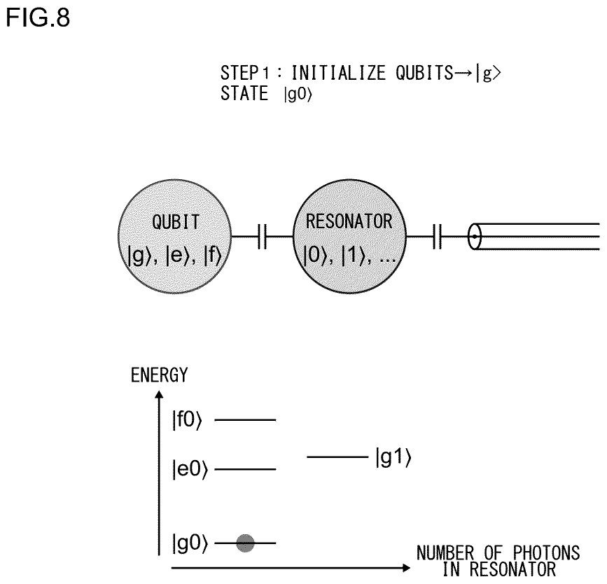

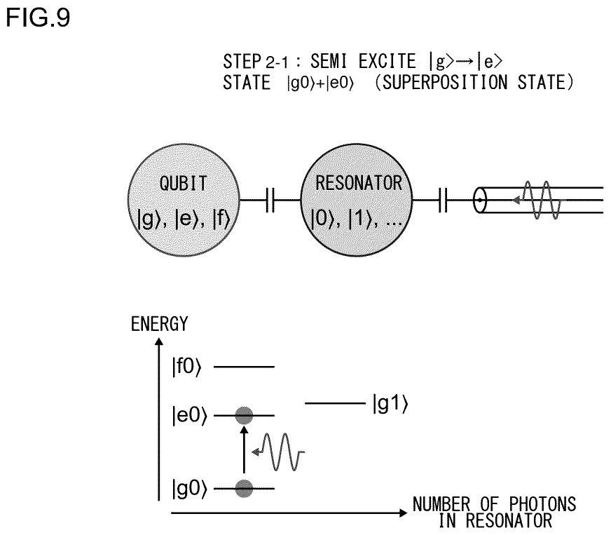

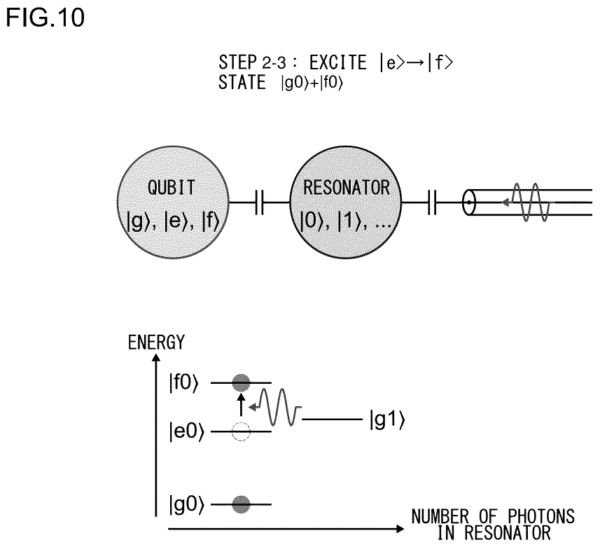

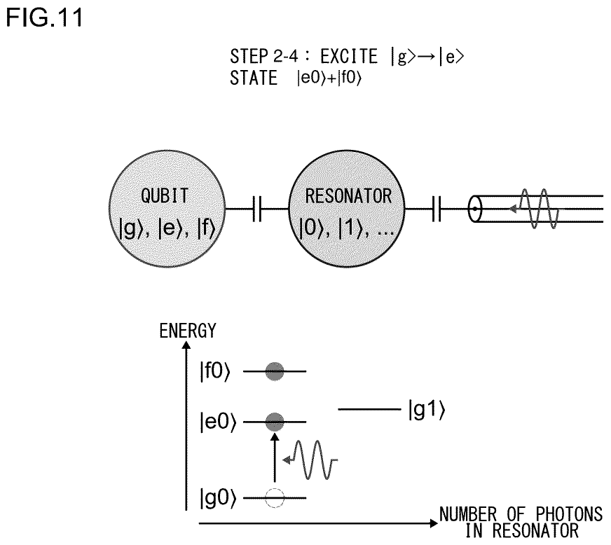

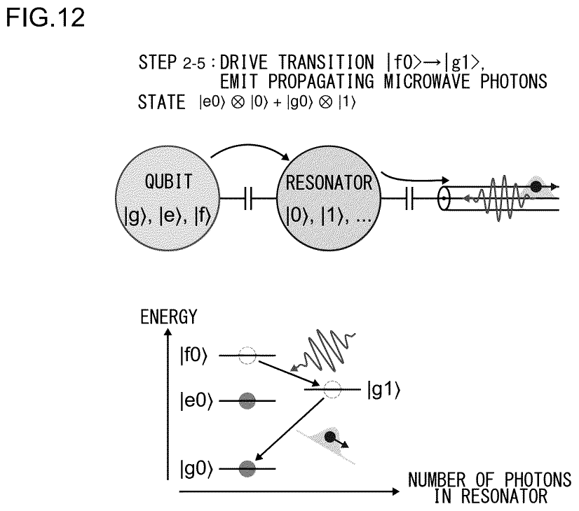

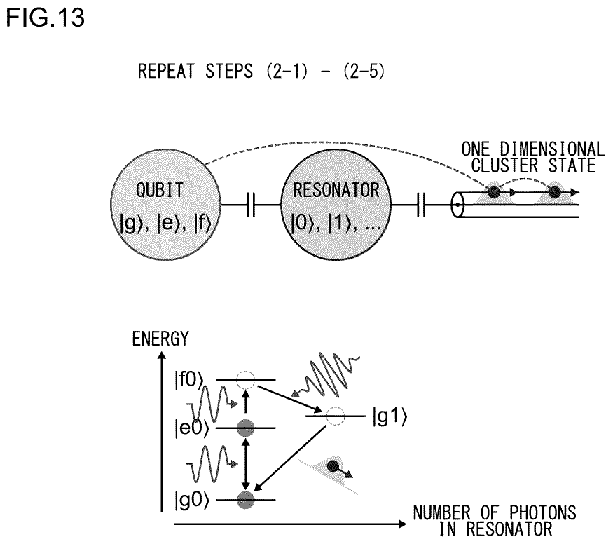

Referring to FIGS. 8 through 13, the procedure for generating a two-dimensional cluster state using the quantum entanglement generator 10 is described below. The symbols are those shown in FIG. 4. two-dimensional cluster states are generated by the following steps.
(Step 1) Initialize the qubits to |g> (FIG. 8).
(Step 2) Repeat the following steps (2-1) to (2-5) “desired photon chain length-1” times (FIG. 13).
(Step 2-1) Semi-excite of |g> to |e> (FIG. 9).
(Step 2-2) Act a controlled-Z gate between two neighboring qubits.
(Step 2-3) Semi-excite the |e> to the |f> (FIG. 10).
(Step 2-4) Excite the |g> to the |e> (FIG. 11).
(Step 2-5) Drive the |f0> to |g1> transition and emit propagating microwave photons (FIG. 12).
(Step 3) Semi-excite the |g> to |e> (FIG. 13).
(Step 4) Act a controlled-Z gate between two neighboring qubits.
(Step 5) Semi-excite the qubits from |e> to |f>.
(Step 6) Drive the |f0> to |g1> transition and emit a propagating microwave photon.

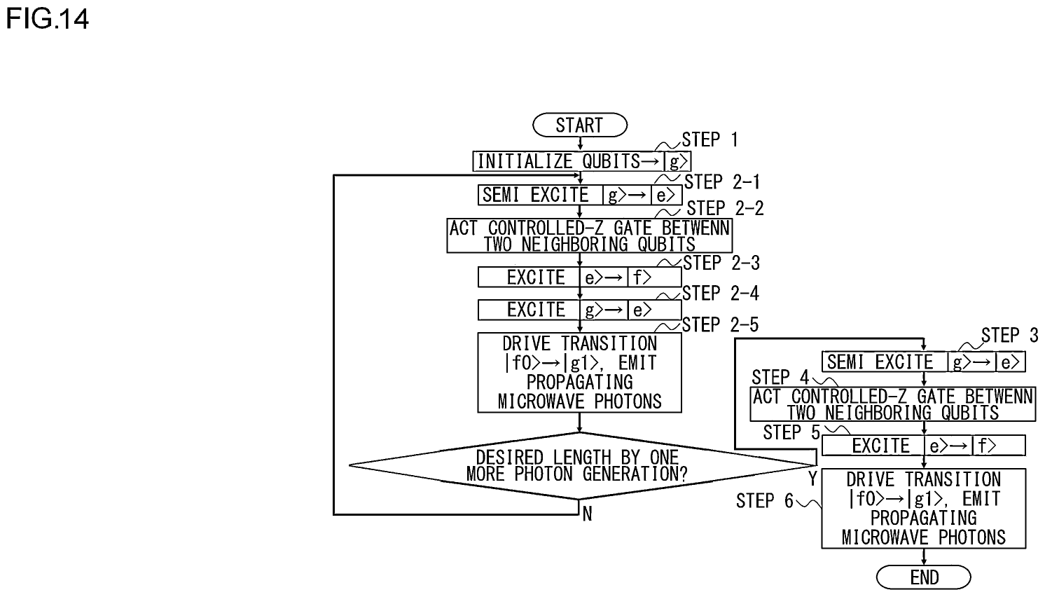

FIG. 14 shows a flowchart of the above procedure for generating cluster states.

The above procedure can generate a two-dimensional cluster state consisting of two microwave photon rows of arbitrary length.

In the above embodiment, the quantum entanglement generator is equipped with a conductor cavity. However, it is not limited to this and can be any suitable enclosure as long as it can electromagnetically isolate the superconducting qubit and microwave resonator from the outside world. For example, if coplanar resonators are employed instead of coaxial line resonators and coplanar waveguides instead of coaxial lines, implementation without a conductor cavity is possible.

In the above embodiment, the entanglement generation qubit and the photon emission qubit were integrated into a single superconducting qubit element. However, this is not limited to this, and a photon emission resonator or photon emission qubit may be provided independently of the entanglement generation qubit.

According to this embodiment, it is possible to realize a device for generating a two-dimensional cluster state of qubits.

### The Second Embodiment

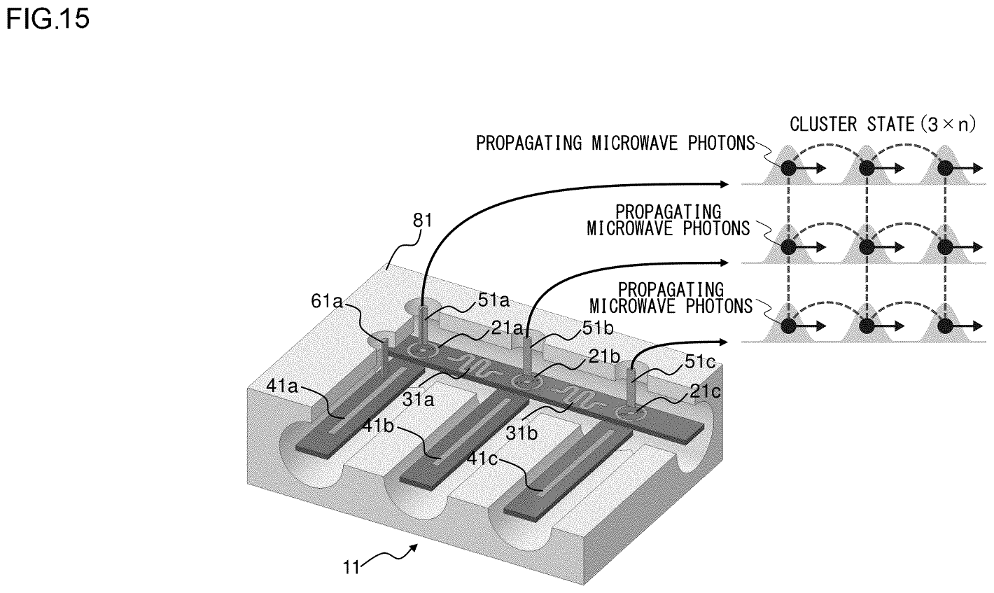

FIG. 15 schematically shows the quantum entanglement generator 11 of the second embodiment. The quantum entanglement generator 11 has superconducting qubit elements 21a, 21b and 21c, coupling resonators 31a and 31b, readout resonators 41a, 41b and 41c, waveguides 51a, 51b and 51c, readout lines 61a, 61b and 61c, and conductor cavity 81. The readout lines 61b and 61c are omitted from the figure to avoid complication of the figure. In other words, the quantum entanglement generator 11 comprises a superconducting qubit element 21c, a coupling resonator 31b, a readout resonator 41c, a waveguide 51c, and a readout line 61c, in addition to the configuration of the quantum entanglement generator 10 in FIG. 6.

The superconducting qubit element 21a and the coupling resonator 31a are capacitively coupled to each other. The superconducting qubit element 21b is capacitively coupled to the coupling resonator 31a and the coupling resonator 31b. The superconducting qubit element 21c and the coupling resonator 31b are capacitively coupled to each other.

The superconducting qubit element 21a and the readout resonator 41a are capacitively coupled to each other. Similarly, the superconducting qubit element 21b and the readout resonator 41b are capacitively coupled to each other. Similarly, the superconducting qubit element 21c and the readout resonator 41c are capacitively coupled to each other.

The superconducting qubit element 21a and the waveguide 51a are capacitively coupled to each other. Similarly, the superconducting qubit element 21b and the waveguide 51b are capacitively coupled to each other. Similarly, superconducting qubit element 21c and waveguide 51c are capacitively coupled to each other.

Readout resonator 41a and readout line 61a are capacitively coupled to each other. Similarly, the readout resonator 41b and the readout line 61b are capacitively coupled to each other. Similarly, readout resonator 41c and readout line 61c are capacitively coupled to each other.

A two-qubit gate can act between adjacent superconducting qubit elements 21a and 21b. Similarly, a two-qubit gate can act between an adjacent superconducting qubit element 21b and a superconducting qubit element 21c.

The detailed procedure of cluster state generation is the same as in the first embodiment, and therefore, the description is omitted.

While the quantum entanglement generator 10 in FIG. 6 generates two-dimensional cluster states consisting of two rows of propagating microwave photons, the quantum entanglement generator 11 generates two-dimensional cluster states consisting of three rows of propagating microwave photons. In other words, this system can generate a larger-scale two-dimensional cluster state.

### The Third Embodiment

The third embodiment is a quantum entanglement generation method. This method generates a quantum entanglement using the quantum entanglement generator described above. The method consists of the first step of initializing the qubit to the ground state, the second step of semi-exciting the ground state to the first excited state, the third step of exciting the first excited state to the second excited state, the fourth step of exciting the ground state to the first excited state, driving the transition from the second excited state, and then propagating microwave photons are emitted from the resonator into the waveguide in the fifth step. According to this embodiment, it is possible to generate a two-dimensional cluster state of propagating microwave photons using a quantum entanglement generator.

### The Fourth Embodiment

The fourth embodiment is a quantum computer. This quantum computer is equipped with the quantum entanglement generator described above. In particular, this quantum computer may perform a measurement-based quantum computation, in which measurements are repeated on the quantum entanglements (cluster states) generated by the aforementioned quantum entanglement generator. According to this embodiment, it is possible to realize a quantum computer that can perform large-scale quantum computation with relatively small hardware.

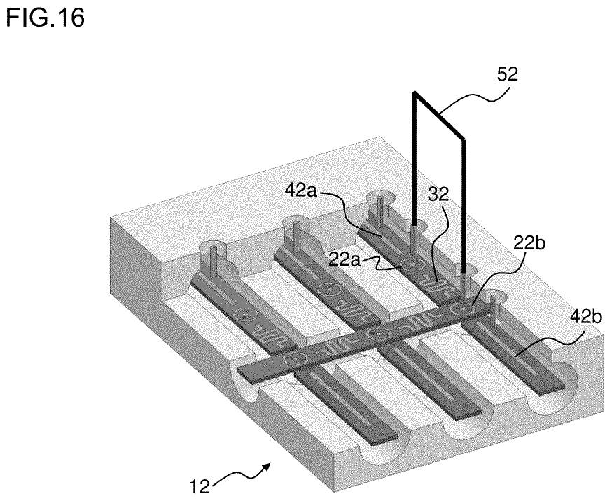

FIG. 16 schematically shows the quantum computer 12 of the fourth embodiment. The quantum computer 12 has a superconducting qubit element 22a, a superconducting qubit element 22b, a coupling resonator 32, a readout resonator 42a, a readout resonator 42b, and a superconducting delay line 52. The superconducting qubit element 22a functions as a qubit element for photon absorption and basis conversion. The superconducting qubit element 22b functions as an entanglement generation qubit and a photon emission qubit. Coupling resonator 32 functions as a coupling resonator mediating a two-qubit gate to generate quantum entanglement between propagating photons emitted at different times. Readout resonator 42a functions as a readout resonator for the basis conversion qubits. The readout resonator 42b functions as the readout resonator of the photon emission qubits.

The quantum computer 12 may, for example, perform a measurement-based quantum computation in the following process. That is, the quantum computer 12 temporarily stores the quantum entanglement (cluster state) generated by the superconducting qubit element 22b as a propagating photon in the superconducting delay line 52, absorbs the propagating photon with the superconducting qubit element 22a, performs a basis transformation, and then makes a measurement and repeats the next measurement while selecting the basis based on result of the immediately preceding measurement.

As a variant of the quantum computer 12, for example, the following quantum computer may be realized. This variant is a quantum computer in which quantum entanglement is generated between propagating photons emitted at different times by applying a controlled-Z gate between the superconducting qubit elements 22a, which have absorbed propagating photons taken out from the superconducting delay line 52, and 22b, and three-dimensional cluster state using time multiplexing is generated.

As a variant of the quantum computer 12, a quantum computer with an error correction function using three-dimensional cluster states may be realized.

The above is a description of the present disclosure based on the embodiments. It is understood by those skilled in the art that these embodiments are examples, that various variations are possible in the combination of each component and each processing process, and that such variations are also within the scope of the disclosure.

Any combination of the above mentioned embodiments and variations is also useful as an embodiment of the disclosure. The new embodiment resulting from the combination will have the combined effects of each of the embodiments and variations combined.

What is claimed is:

1. A quantum entanglement generator, comprising:
n qubit elements, wherein n is an integer greater than or equal to 2,
a coupling resonator disposed between adjacent the qubit elements; and
a waveguide capacitively coupled to each of the qubit elements, wherein
the quantum entanglement generator generates a quantum entanglement between the adjacent the qubit elements by causing a two-qubit gate between the adjacent qubit elements using the coupling resonator, and
the quantum entanglement generator emits the quantum entanglement as a propagating microwave photon into the waveguide, thereby the quantum entanglement generator generates a two-dimensional cluster state.

2. The quantum entanglement generator according to claim 1, wherein each of the n qubit elements has three electrodes.

3. The quantum entanglement generator according to claim 1, wherein the quantum entanglement generator includes a photon emission qubit that transfers the quantum entanglement to the propagating microwave photon and emits the propagating microwave photon into the waveguide.

4. The quantum entanglement generator according to claim 1, comprising a photon emission resonator or a photon emission qubit that transfers the quantum entanglement to the propagating microwave photon and emits the propagating microwave photon into the waveguide, independently of the qubit element.

5. The quantum entanglement generator according to claim 1, comprising a readout resonator for reading out a state of the qubit element.

6. The quantum entanglement generator according to claim 2, wherein two of the three electrodes have a shape of a circular ring cut in half with concentric contours when viewed from the direction of the waveguide.

7. The quantum entanglement generator according to claim 1, comprising a conductor cavity with a cavity penetrating therein, wherein the qubit elements and the coupling resonator are fixed within the cavity of the conductor cavity.

8. The quantum entanglement generator according to claim 1, wherein
the qubit element initializes a qubit to a ground state, semi-excites the ground state to a first excited state, excites the first excited state to a second excited state, excites the ground state to the first excited state, drives a transition from the second excited state, and then emits the propagating microwave photon from the resonator into the waveguide and semi-excites the first excited state to the second excited state.

9. The quantum entanglement generator according to claim 1, wherein that the qubit element is a superconducting qubit element.

10. A method of generating quantum entanglement using a quantum entanglement generator according to claim 1, comprising
initializing a qubit to a ground state,
semi-exciting the ground state to a first excited state,
exciting the first excited state to a second excited state,
exciting the ground state to the first excited state,
emitting a propagating microwave photon from the resonator into the waveguide after driving a transition from the second excited state and
semi-exciting the first excited state to the second excited state.

11. A quantum computer equipped with a quantum entanglement generator according to claim 1.

12. The quantum computer according to claim 11, wherein it performs a measurement-based quantum computation in which a measurement is repeated for a quantum entanglement generated by the quantum entanglement generator.

13. The quantum computer according to claim 11, wherein it stores temporarily a quantum entanglement generated by the quantum entanglement generator from the waveguide to a superconducting delay line as a propagating photon, makes the quantum entanglement interact with a photon generating device again and performs a measurement-based quantum computation in which measurement is repeated while selecting a next measurement basis based on a result of a previous measurement using a measurement device with a basis.
